(19) United States
(12) Patent Application Publication
(10) Pub. No.: US 2008/0020594 A1
(43) Pub. Date: Jan. 24, 2008

(54) Methods of manufacturing a phase-changeable memory device

(76) Inventors: Do-Hyung Kim, Gyeonggi-do (KR); Ju-Bum Lee, Gyeonggi-do (KR)

Correspondence Address: MYERS BIGEL SIBLEY & SAJOVEC, PO BOX 37428, RALEIGH, NC, 27627, US

(21) Appl. No.: 11/827,777

(22) Filed: Jul. 13, 2007

(30) Foreign Application Priority Data
Jul. 24, 2006 (KR) 2006-68925

(51) Int. Cl. H01L 21/31

(52) U.S. Cl. 438/787; 257/E21.24

(57) ABSTRACT

In a method of manufacturing a phase-changeable memory device, a lower electrode is formed on a substrate. Silicon oxynitride is then deposited on the lower electrode at a temperature of about 450° C. to about 650° C. to form an insulating interlayer that is relatively dense on the lower electrode. The insulating interlayer is partially etched to form a contact hole exposing the lower electrode. A phase-changeable material layer pattern filling up the contact hole is formed on the insulating interlayer such that the phase-changeable material layer pattern makes contact with the lower electrode.

### CROSS-REFERENCE TO RELATED APPLICATION

This application is related to and claims priority under 35 USC § 119 from Korean Patent Application No. 2006-68925 filed on Jul. 24, 2006 in the Korean Intellectual Property Office, the disclosure of which is incorporated herein by reference in its entirety

### BACKGROUND OF THE INVENTION

The present invention relates to methods of manufacturing a semiconductor device, and more particularly, to methods of manufacturing a phase-changeable random access memory (PRAM).

A semiconductor memory device may be classified as either a volatile memory device or a non-volatile memory device. The volatile memory device may be a dynamic random access memory (DRAM) or a static random access memory (SRAM). The volatile memory device may lose its data when power to the device is lost or a time period elapses. On the other hand, the non-volatile memory device may retain its data even when power is removed.

Thus, the non-volatile memory device may store data for an indefinite period. A flash memory, capable of inputting and outputting data, is a type of non-volatile memory that is becoming very popular. However, an operation speed of the non-volatile memory device (e.g. a flash memory device) for reading or writing data may be substantially slower than that of a dynamic random access memory (DRAM) device, where data may be written or retrieved randomly as contrasted with the access approach for flash memory devices.

Accordingly, a new type of memory device having the advantage of retaining its data even when its power is lost combined with and a relatively fast operation speed has been developed. The new memory device may be classified in accordance with a material included in a memory cell. For example, the new memory device may be a ferroelectric random access memory (FRAM) device, a magnetic random access memory (MRAM), a phase-changeable random access memory (PRAM) device, a polymer random access memory (PoRAM) device, a nanotube random access memory device, a holographic random access memory device, a modular random access memory device or the like.

The PRAM device is a non-volatile memory device that stores data by using a difference in electric conductivity or resistance between a crystalline phase and an amorphous phase of a predetermined phase-changeable material.

The unit memory cell of a conventional phase-changeable memory device generally includes a switching element (i.e., a memory cell transistor) and a data storage element connected to the switching element. The data storage element generally includes a lower electrode electrically connected to the cell transistor and a phase-changeable material layer that makes contact with the lower electrode.

When a current is applied to a phase-changeable material, a heat is generated in the phase-changeable material. A phase of the phase-changeable material may be changed between a crystalline phase and an amorphous phase by application of sufficient heat. That is, the phase of the phase-changeable material may be changed from the crystalline phase to the amorphous phase. The phase of the phase-changeable material may be also changed from the amorphous phase to the crystalline phase. The phase of the phase-changeable material varies depending on the amount of the current applied to the phase-changeable material and a time for which the current is applied (which correspond to the heat generated in the phase-changeable material). A resistance of the phase-changeable material may vary depending on the phase of the phase-changeable material. For example, when the current applied to the phase-changeable material layer in the phase-changeable memory device through the switching device and the lower electrode changes the phase of the phase-changeable material layer into the crystalline phase having a relatively low resistance, a value of “0” may be recognized. On the other hand, when the applied current changes the phase of the phase-changeable material layer into the amorphous phase having a relatively large resistance, a value of “1” may be recognized.

FIGS. 1A and 1B are cross-sectional views illustrating a conventional method of manufacturing a phase-changeable memory device. Referring to FIG. 1A, an insulating layer 14 is formed on a semiconductor substrate 10 having a surface where an impurity region 12 is formed. The insulating layer 14 is then etched by a photolithography process to form a first contact hole 16 partially exposing the impurity region 12.

A conductive layer is formed on the insulating layer 14 to fill up the first contact hole 16 using, for example, tungsten (W). The conductive layer is then planarized until the insulating layer 14 is exposed so that a lower electrode 18 filling up the first contact hole 16 may be formed.

Silicon nitride is deposited on the lower electrode 18 and the insulating layer 14 by a plasma-enhanced chemical vapor deposition (PECVD) process to form an etch stop layer 20. Silicon oxynitride (SiON) is then deposited on the etch stop layer 20 by a PECVD process at a temperature of about 400° C. to form an insulating interlayer 22. Oxide is then deposited on the insulating interlayer 22 by a PECVD process to form a hard mask layer 24.

Referring to FIG. 1B, the hard mask layer 24, the insulating interlayer 22 and the etch stop layer 20 are etched by a photolithography process to form a second contact hole 26 partially exposing the lower electrode 18. A silicon nitride layer is then formed on the hard mask layer 24 to fill the second contact hole 26 by a low-pressure chemical vapor deposition (LPCVD) process at a temperature of about 650° C. to about 750° C. Thereafter, the silicon nitride layer is anisotropically etched to form a contact spacer 28 on sidewalls of the second contact hole 26. The contact spacer 28 reduces a contact area between the lower electrode 18 and the phase-changeable material layer that is to be formed. Thus, a phase transition efficiency of the phase-changeable material layer may be improved.

A phase-changeable material layer is then formed on the hard mask layer 24 to fill up the second contact hole 26 having the sidewalls on which the contact spacer 28 is formed. The phase-changeable material layer may be formed using a chalcogenide including germanium (Ge), antimony (Sb) and tellurium (Te). The phase-changeable material layer is then patterned by a photolithography process to form a phase-changeable layer pattern 30.

In the above conventional method of manufacturing the phase-changeable memory device, silicon oxynitride (SiON) is deposited by a plasma-enhanced chemical vapor deposition (PECVD) process at a low temperature of about 400° C. to form the insulating interlayer 22 between the lower electrode 18 and the phase-material layer pattern 30. Generally, when a temperature at which the insulating interlayer 22 is formed by the PECVD process decreases, the number of pores formed in the insulating interlayer 22 may increase. Thus, an insulation characteristic of the insulating interlayer 22 may decrease when the insulating interlayer 22 is formed at a relatively low temperature. In addition, the porous insulating interlayer 22 formed under the above conditions may be shrunk when silicon nitride is deposited by a low pressure chemical vapor deposition (LECVD) process at a high temperature over about 650° C. to form the contact spacer 28. In this case, as illustrated in FIG. 2, the sidewalls of the second contact hole 26 formed over the lower electrode 18 may become bent. That is, a defect, such as a bowing, may be generated at the sidewall of the second contact hole 26.

The defect, such as the bowing, may increase an aspect ratio of the second contact hole 26 so that a void and/or a seam may be generated in the second contact hole 26 when the phase-changeable material layer filling up the second contact hole 26 is formed. Thus, an electric characteristic of the phase-changeable memory device may be deteriorated.

When an additional annealing process is performed on the porous insulating interlayer 22 formed by the PECVD process, the porous insulating interlayer 22 may become dense. Accordingly, the defect, such as the bowing, may be limited or even prevented by performing the additional annealing process on the porous insulating interlayer 22 before the second contact hole 26 is formed. However, when the additional annealing process is performed, processes for manufacturing the phase-changeable memory device may become complex. In addition, a cost for manufacturing the phase-changeable memory device may increase.

### SUMMARY OF THE INVENTION

Embodiments of the present invention include methods of manufacturing a phase-changeable memory device. A lower electrode is formed on a substrate. An insulating interlayer having a selected density is formed on the lower electrode by depositing silicon oxynitride on the lower electrode at a temperature of about 450° C. to about 650° C. The insulating interlayer is partially etched to form a contact hole exposing the lower electrode and a phase-changeable material layer pattern is formed in the contact hole in the insulating interlayer that contacts the lower electrode.

In further embodiments, the insulating interlayer is formed to have a refraction index of about 1.7 to about 1.9. The insulating interlayer may be formed using a plasma-enhanced chemical vapor deposition process and/or a low-pressure chemical vapor deposition process. Forming the insulating interlayer may be preceded by forming an etch stop layer on the lower electrode. Forming the etch stop layer may include depositing silicon nitride using a plasma-enhanced chemical vapor deposition process.

In other embodiments, partially etching the insulating interlayer is preceded by forming a hard mask on the insulating interlayer. Forming the hard mask may include depositing oxide by a plasma-enhanced chemical vapor deposition process. Forming the phase-changeable material layer pattern may be preceded by forming a contact spacer on sidewalls of the contact hole. Forming the contact spacer may include depositing silicon nitride using a low chemical vapor deposition process. Forming the insulating interlayer may include depositing silicon oxynitride at a temperature of about 550° C. and forming the contact spacer may include depositing a nitride at a temperature of about 650° C. to about 750° C.

In further embodiments, forming a phase-changeable material layer pattern is preceded by forming a high resistance material layer in the contact hole. Forming the high resistance material layer may include forming the high resistance material layer using titanium aluminum nitride. The phase-changeable material layer may fill the contact hole.

In yet other embodiments, methods of manufacturing a phase-changeable memory device are provided. An impurity region is formed in a substrate and a first insulating layer is formed on the substrate. The first insulating layer is partially etched to form a first contact hole exposing the impurity region. A lower electrode is formed filling the first contact hole. The lower electrode contacts the impurity region. A second insulating layer having a selected density is formed on the lower electrode by depositing silicon oxynitride on the lower electrode at a temperature of about 450° C. to about 650° C. The second insulating layer is partially etched to form a second contact hole exposing the lower electrode. A phase-changeable material layer pattern is formed filling the second contact hole. The phase-changeable material layer pattern contacts the lower electrode.

In further embodiments, the second insulating layer is formed to have a refraction index of about 1.7 to about 1.9. Forming the second insulating layer may include forming the second insulating layer using a plasma-enhanced chemical vapor deposition process and/or a low-pressure chemical vapor deposition process. Forming the second insulating layer may be preceded by forming an etch stop layer including silicon nitride on the lower electrode and the first insulating layer using a plasma-enhanced chemical vapor deposition process. Partially etching the second insulating layer may be preceded by forming a hard mask including oxide on the second insulating layer using a plasma-enhanced chemical vapor deposition process.

In other embodiments, forming the phase-changeable material layer pattern is preceded by forming a contact spacer including silicon nitride on sidewalls of the second contact hole using a low-pressure chemical vapor process. Forming the phase-changeable material layer pattern may be preceded by forming a high resistance material layer including titanium aluminum nitride in the second contact hole.

### BRIEF DESCRIPTION OF THE DRAWINGS

The above and other features and advantages of the present invention will become more apparent by describing in detailed embodiments thereof with reference to the accompanying drawings, in which:

FIGS. 1A and 1B are cross-sectional views illustrating a conventional method of manufacturing a phase-changeable memory device;

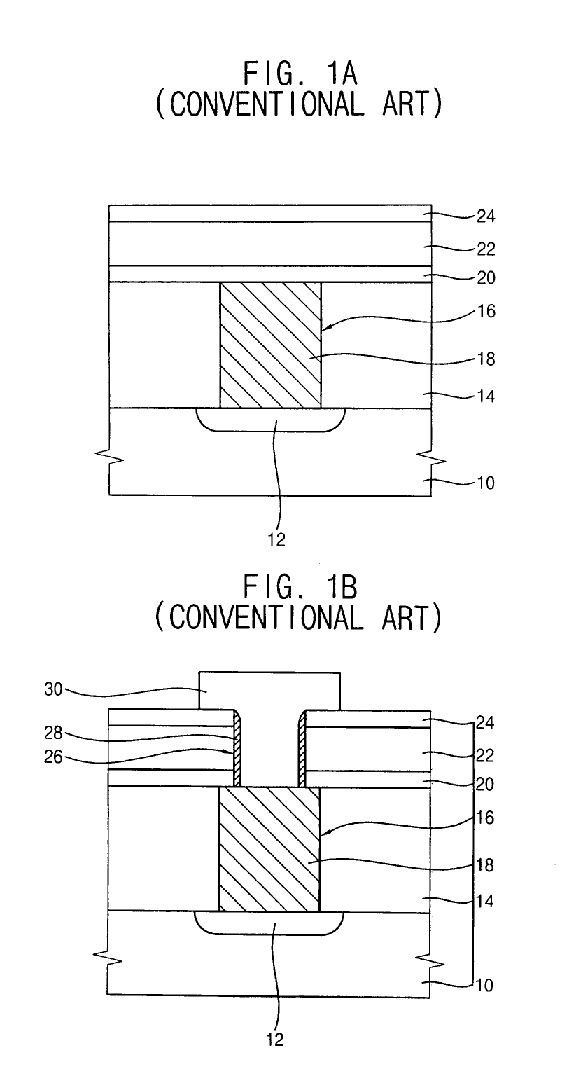

FIG. 2 is an enlarged cross-sectional view illustrating a defect of a conventional phase-changeable memory device;

FIGS. 3A to 3D are cross-sectional views illustrating methods of manufacturing a phase-changeable memory device in accordance with some embodiments of the present embodiment;

FIGS. 4A and 4B are graphs illustrating electric properties, such as a reset current (Ireset, A) and a set resistance (Rset, Ω), of phase-changeable memory devices manufactured by a conventional manufacturing method and by some embodiments of the present invention;

FIG. 5 is a graph illustrating electric properties of a conventional phase-changeable memory device and a phase-changeable memory device of some embodiments of the present invention based on a difference in a refraction index of silicon oxynitride; and

FIG. 6 is a graph comparing insulation reliabilities of the insulating interlayers of a conventional phase-changeable memory device and a phase-changeable memory device of some embodiments of the present invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper”? and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

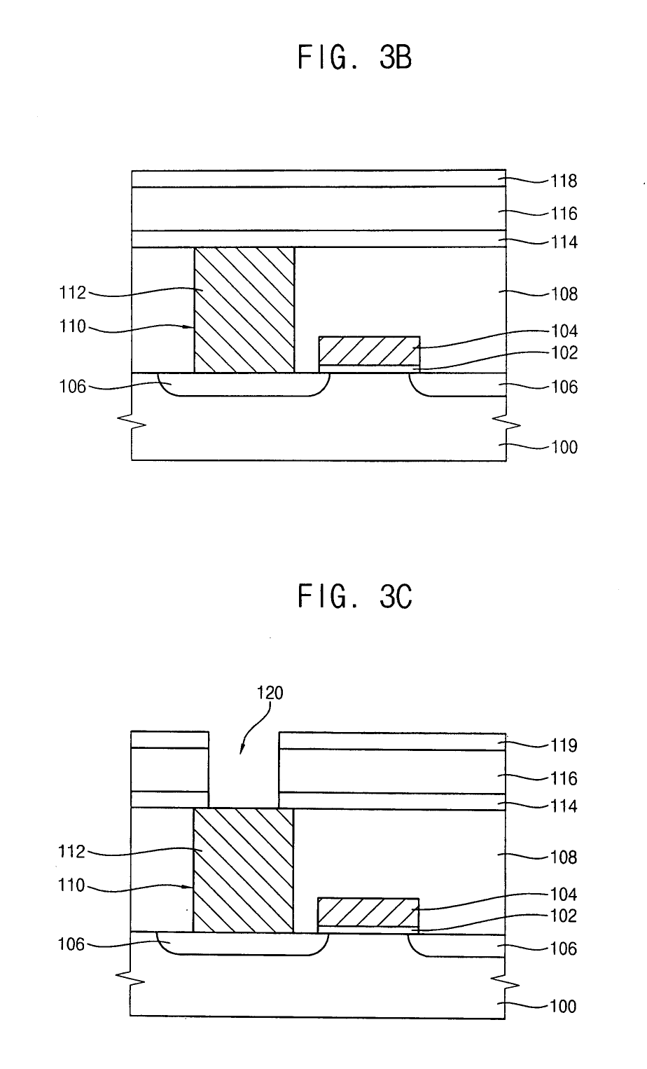

Some embodiments of the present invention will now be described with reference to FIGS. 3A to 3D. More particularly, FIGS. 3A to 3D are cross-sectional views illustrating a method of manufacturing a phase-changeable memory device in accordance with some embodiments of the present embodiment.

Referring to FIG. 3A, an isolation layer (not shown) is formed at a surface portion of a semiconductor substrate 10 by an isolation process, such as a shallow trench isolation (STI) process. The semiconductor substrate 100 may be a silicon wafer and/or a silicon-on-insulator (SOI) substrate. The isolation layer may correspond to a field region of the semiconductor substrate 100. A portion of the semiconductor substrate 100 enclosing the isolation layer may correspond to an active region of the semiconductor substrate 100.

A gate insulating layer 102 is formed on the active region of the semiconductor substrate 100. A gate electrode 104 is formed on the gate insulating layer 102. The gate insulating layer 102 may be formed using a silicon oxide by a thermal oxidation process and/or a chemical vapor deposition (CVD) process. In some embodiments, the gate insulating layer 102 is formed using a metal oxide by a CVD process, a sputtering process, an atomic layer deposition process, a pulse laser deposition process, an electron beam deposition process and/or the like. For example, the gate insulating layer 102 may include silicon oxide, hafnium oxide, zirconium oxide, aluminum oxide, tantalum oxide, titanium oxide and/or the like.

The gate electrode may have a single-layered structure. The gate electrode 104 having the single-layered structure may be a metal layer or a polysilicon layer heavily doped with impurities. In some embodiments, the gate electrode 104 may have a multi-layered structure. In this case, the gate electrode 104 may include at least one metal layer and/or at least one polysilicon layer heavily doped with impurities.

A gate structure including the gate insulating layer 102 and the gate electrode 104 is formed on the active region by a formation of the gate electrode 104. A gate capping layer may be further formed on the gate electrode 104 included in the gate structure. The gate capping layer may be formed using a material having an etching selectivity with respect to the gate electrode 104 and the gate insulating layer 102. For example, when the gate electrode 104 located on the gate insulating layer 102 including oxide includes metal or polysilicon heavily doped with impurities, the gate capping layer may include a nitride, such as silicon nitride, or an oxynitride, such as silicon oxynitride.

A gate spacer may be further formed on sidewalls of the gate electrode. The gate spacer may be formed using a material having an etching selectivity with respect to the gate electrode 104 and the gate insulating layer 102. For example, the gate spacer may be formed using a silicon nitride and/or a silicon oxynitride. In some embodiments, the gate spacer may be formed using a material substantially the same as or similar to that included in the gate capping layer.

Referring again to FIG. 3A, impurities are implanted into portions of the semiconductor substrate 100 adjacent to the gate structure, for example, by an ion implantation process using the gate structure as an ion implantation mask, so that impurity regions 106 adjacent to the gate structure may be formed. The impurity regions correspond to contact regions. For example, the impurity regions 106 may be source/drain regions. The impurity regions 106 may be formed in the semiconductor substrate 100 by the ion implantation process and/or a thermal treatment process. Accordingly, cell transistors including the gate structure 104 and the impurity regions 106 may be formed on the semiconductor substrate 100. The cell transistor may have a switching function for an addressing operation and a read/write operation of a memory cell.

An insulating layer 108 is formed on the semiconductor substrate 100 where the cell transistors are formed to cover the gate structure 104. The insulating layer 108 may be formed using, for example, an oxide, such as tetraethylorthosilicate (TEOS), undoped silicate glass (USG), spin-on-glass (SOG), flowable oxide (FOX), high density plasma-chemical vapor deposition (HDP-CVD) oxide and/or the like. The insulating layer 108 may be formed by a chemical vapor deposition process, a low pressure chemical vapor deposition process, a plasma-enhanced vapor deposition process, a high density vapor-chemical vapor deposition process and/or the like.

A photoresist pattern (not shown) is formed on the insulating layer 108. The insulating layer 108 is partially etched using the photoresist pattern as an etching mask to form a first contact hole 110. One of the impurity regions 106 is partially exposed through the first contact hole 110. The photoresist pattern is removed from the insulating layer 108, for example, by an ashing process and/or a stripping process, after the first contact hole 110 is formed.

A conductive layer (not shown) filling up the first contact hole 110 is formed on the insulating layer 108. The conductive layer may be formed using metal and/or polysilicon doped with impurities. The metal may be copper, tantalum, tungsten, titanium, aluminum and/or the like. For example, the conductive layer may be formed using tungsten.

The conductive layer is removed by a chemical mechanical polishing (CMP) process, an etch-back process or a combination process of the CMP process and the etch-back process until the insulating layer 108 is exposed. Thus, a lower electrode 112 filling up the first contact hole 110 is formed with the lower electrode 112 contacting with the impurity region 106. The lower electrode 112 may have a contact shape or a plug shape.

Referring to FIG. 3B, an etch stop layer 114 is formed on the lower electrode 112 and the insulating layer 108. The etch stop layer 114 is formed using a material having an etching selectivity with respect to the insulating layer 108 and the lower electrode 112. For example, the etch stop layer 114 may be formed using a nitride, such as silicon nitride. The etch stop layer 114 may be formed by a plasma-enhanced chemical vapor deposition (PECVD) process, a chemical vapor deposition (CVD) process, a low pressure chemical vapor deposition (LPCVD) process and/or the like. The etch stop layer 114 may protect the insulating layer 108 and the lower electrode 112 while an etching process is performed to form a second contact hole 120 (see FIG. 3C) exposing the lower electrode 112.

An insulating interlayer 116 and a hard mask layer 118 are successively formed on the etch stop layer 114. The insulating interlayer 116 may be formed using silicon oxynitride (SiON) by a PECVD process and/or an LPCVD process. The insulating interlayer 116 may be formed at a relatively high temperature of about 450° C. to about 650° C. Accordingly, the insulating interlayer 116 may be relatively dense. In addition, the insulating interlayer may have a superior insulation characteristic. The silicon oxynitride included in the insulating interlayer 116 may have a refraction index of about 1.7 to about 1.9. When the reflection index of the insulating interlayer 116 is less than about 1.7, the insulating interlayer 116 may become porous so that the insulating interlayer 116 may not be dense. In this case, the cleaning solution may permeate into the insulating interlayer 116. The cleaning solution permeating into the insulating interlayer 116 may undesirably etch the insulating interlayer 116. On the other hand, when the reflection index of the insulating interlayer 116 is more than about 2.0, a reset current of the cell transistor generally increases so that an electrical property of the cell transistor may deteriorate. In some embodiments, silicon oxynitride having a refraction index of about 1.8 is deposited at a relatively high temperature of about 550° C. by a PECVD process so that the insulating interlayer 116 may be formed on the etch stop layer 114.

The hard mask layer 118 that is to be used to form a hard mask 119 (see FIG. 3C) used as an etching mask in an etching process required for forming a second contact hole 120 may be formed using a material having an etching selectivity with respect to the insulating interlayer 116. When the insulating interlayer 116 is formed using oxynitride, the hard mask layer 118 may be formed using an oxide, such as silicon oxide. For example, the hard mask layer 118 may be formed using an oxide such as TEOS, USG, SOG, FOX and/or the like. In addition, the hard mask layer 118 may be formed by a CVD process, an LPCVD process, a PECVD process and/or the like. In some embodiments, an oxide is deposited on the insulating interlayer 116 by a PECVD process to form the hard mask layer 118.

Referring to FIG. 3C, a photoresist film (not shown) is formed on the hard mask layer 118. An exposure process and a development process are then performed on the photoresist film so that a photoresist pattern (not shown) may be formed on the hard mask layer 118. The hard mask layer 118 is etched using the photoresist pattern as the etching mask so that the hard mask 119 may be formed on the insulating interlayer 116.

The photoresist pattern may be removed from the hard mask 119 by an ashing process and/or a stripping process. The insulating interlayer 116 and the etch stop mask 114 are etched using the hard mask 119 as an etching mask. As a result, the second contact hole 120 exposing a portion of the lower electrode 112 may be formed through the insulating interlayer 116 and the etch stop layer 114.

In some embodiments, the photoresist pattern may be removed in the etching process for forming the second contact hole 120. In this case, the ashing process and/or the stripping process required for removing the photoresist pattern from the hard mask 119 may not be performed. In further embodiments, a cleaning process may be additionally performed to remove a native oxide layer formed on the exposed lower electrode 112 or a residue formed in the etching process required for forming the second contact hole 120.

Referring to FIG. 3D, a nitride layer having a relatively uniform thickness is formed on the hard mask 119 to fill up the second contact hole 120. The nitride layer is then etched to form a contact spacer 122 on sidewalls of the second contact hole 120. Silicon nitride may be deposited at a relatively high temperature of about 650° C. to about 750° C. by an LPCVD process to form the nitride layer. The nitride layer may be anisotropically etched to form the contact spacer 122.

The contact spacer 122 decreases an area of a phase-changeable material layer pattern 124 making contact with the lower electrode 112 so that a contact resistance between the lower electrode 112 and the phase-changeable material layer pattern 124 may increase. When the contact resistance between the lower electrode 112 and the phase-changeable material layer pattern 124 increases, a phase transition efficiency of the phase-changeable material layer pattern 124 may be improved.

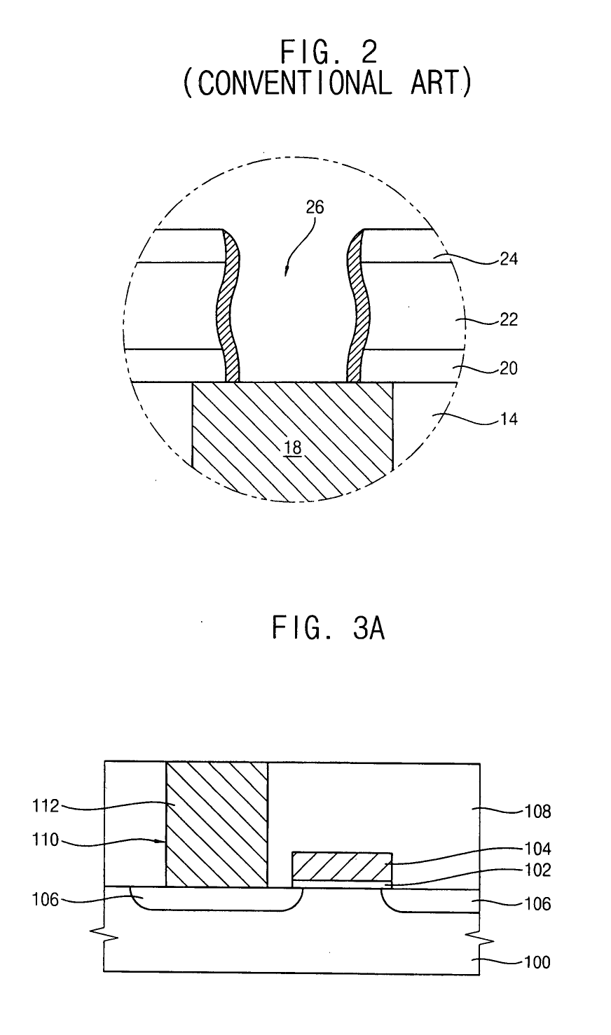

The nitride included in the contact spacer 122 may be deposited at a relatively high temperature of about 650° C. to about 750° C. As such, when the insulating interlayer 116 includes porous silicon oxynitride deposited at a relatively low temperature of about 400° C., the insulating interlayer 116 may shrink so that a profile of the second contact hole 120 exposing the lower electrode 112 may deteriorate. For example, the sidewall of the second contact hole 120 may become bent as seen in FIG. 2.

In some embodiments of the present invention, the silicon oxynitride is deposited at a high temperature of about 550° C. to form the insulating interlayer 116 that is relatively dense (as contrasted with the conventional layer deposited at about 400° C.) and the nitride is deposited at a relatively high temperature of about 650° C. to about 750° C. to form the contact spacer 122. Thus, the insulating interlayer 116 may not be shrunk. Accordingly, the profile of the second contact hole 120 exposing the lower electrode 112 may not be deteriorated. For example, the sidewall of the second contact hole 120 may not become bent.

A phase-changeable material layer (not shown) filling up the second contact hole 120 is formed after the contact spacer 122 is formed on the sidewalls of the second contact hole 120. The phase-changeable material layer is then patterned by a photolithography process to form the phase-changeable material layer pattern 124 on the lower electrode 112 and the hard mask 119.

A chalcogenide compound may be deposited by a sputtering process to form the phase-changeable material layer on the lower electrode 112. When a current is applied to the chalcogenide compound, heat may be generated. The heat, depending on the amount of current and a time to which the current is applied, may vary a crystalline state of the chalcogenide compound. The chalcogenide compound may be an element in Group V-antimony-tellurium. Examples of the element in Group V-antimony-tellurium may include germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te), tantalum (Ta), niobium (Nb) and/or vanadium (V). In some embodiments, the chalcogenide compound is an element in Group VI-antimony-tellurium. Examples of the element in Group VI-antimony-tellurium may include tungsten (W), molybdenum (Mo) and/or chromium (Cr). In further embodiments, the chalcogenide compound is an element in Group V-antimony-selenium. In still further embodiments, the chalcogenide compound may be an element in Group VI-antimony-selenium. In some embodiments of the present invention, the phase-changeable material layer may be formed using germanium-antimony-tellurium (GST) such that the phase-changeable material layer has a thickness of about 100 Å to about 1000 Å measured from an upper face of the lower electrode 112.

In some embodiments, to increase the phase transition efficiency of the phase-changeable material pattern 124, the second contact hole 120 is partially filled with a high resistance material layer. The phase-changeable material layer may be formed on the high resistance material layer to fill up the second contact hole 120. The high resistance material layer may be formed using titanium aluminum nitride (TiAlN).

Generally, a high temperature of over about 900° C. is required for the phase change of the phase-changeable material layer pattern 124. The high temperature may be obtained by Joule heat generated by a current applied to the phase-changeable material layer pattern 124. The current may be applied to the phase-changeable material layer pattern 124 by using the lower electrode 112 and the cell transistor, which is used as a switching device.

When the phase-changeable material layer pattern 124 is rapidly cooled after the phase-changeable material layer pattern 124 is heated over a melting temperature by the current flowing through the phase-changeable material layer pattern 124, a phase of the phase-changeable material layer pattern 124 may become an amorphous phase having a relatively high resistance. In this case, the phase-changeable material layer pattern 124 may store information of “1.” The state of the phase-changeable material layer pattern 124 storing the information of “1” is defined as a reset state.

When the phase-changeable material layer pattern 124 is slowly cooled over a relatively long time after the phase-changeable material layer pattern 124 is heated over a crystallization temperature by the current flowing through the phase-changeable material layer pattern 124, the phase of the phase-changeable material layer pattern 124 may become a single crystalline phase having a relatively low resistance. In this case, the phase-changeable material layer pattern 124 may store information of “0.” The state of the phase-changeable material layer pattern 124 storing the information of “0” is defined as a set state.

An upper electrode, a wire line, a protection layer and/or an additional insulating layer may be formed on the phase-changeable material layer pattern 124 after the phase-changeable material layer pattern 124 is formed on the lower electrode 112. Thus, the phase-changeable memory device may be manufactured.

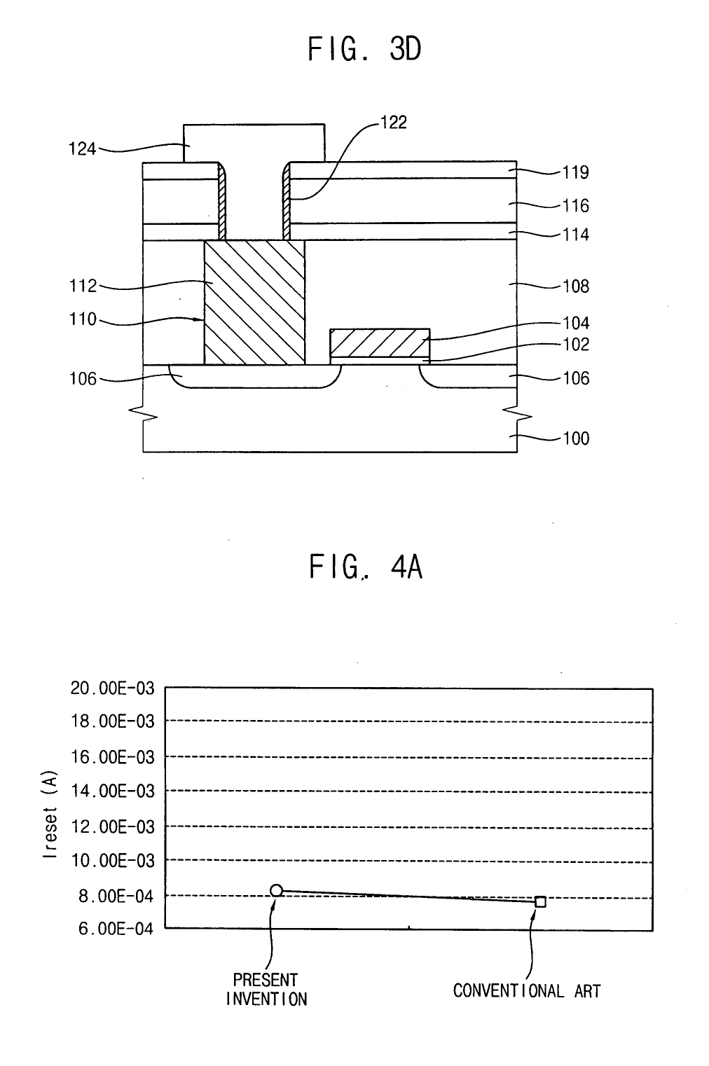

FIGS. 4A and 4B are graphs illustrating electric properties, such as a reset current (Ireset, A) and a set resistance (Rset, Ω), of phase-changeable memory devices manufactured by a conventional manufacturing method and by some embodiments of the present invention.

Referring to FIGS. 4A and 4B, “▪” and “□” represent a reset current and a set resistance, respectively, of a conventional phase-changeable memory device. “” and “∘” represent the reset current and the set resistance, respectively, of a phase-changeable memory device for some embodiments of the present invention. In a conventional method of manufacturing a phase-changeable memory device, silicon oxynitride having a refraction index of about 2.1 is deposited at a low temperature of about 400° C. by a plasma-enhanced chemical vapor deposition (PECVD) process to form an insulating interlayer. An annealing process is then performed to densify the insulating interlayer. In a method of manufacturing a phase-changeable memory device of some embodiments of the present invention, a plasma enhance chemical vapor deposition (PECVD) process is performed after a silane (SiH₄) gas, an ammonia (NH₃) gas and a nitrous oxide (N₂O) gas are supplied as a silicon source gas, a nitrogen-containing gas and an oxygen-containing gas, receptively, at a relatively high temperature of about 550° C. The flow rates of the silane (SiH₄) gas, the ammonia (NH₃) gas and the nitrous oxide (N₂O) gas are about 79 sccm, about 30 sccm and about 40 sccm, respectively. Thus, an insulating interlayer insulating silicon oxynitride having a refraction index of about 1.8 is formed. A reset current is used for melting the phase-changeable material layer. In addition, the smaller the reset current, the greater the electric property is represented.

As illustrated in FIGS. 4A and 4B, the phase-changeable memory device of some embodiments of the present invention including silicon oxynitride deposited at a relatively high temperature of about 550° C. has substantially similar electric properties to the conventional phase-changeable memory device.

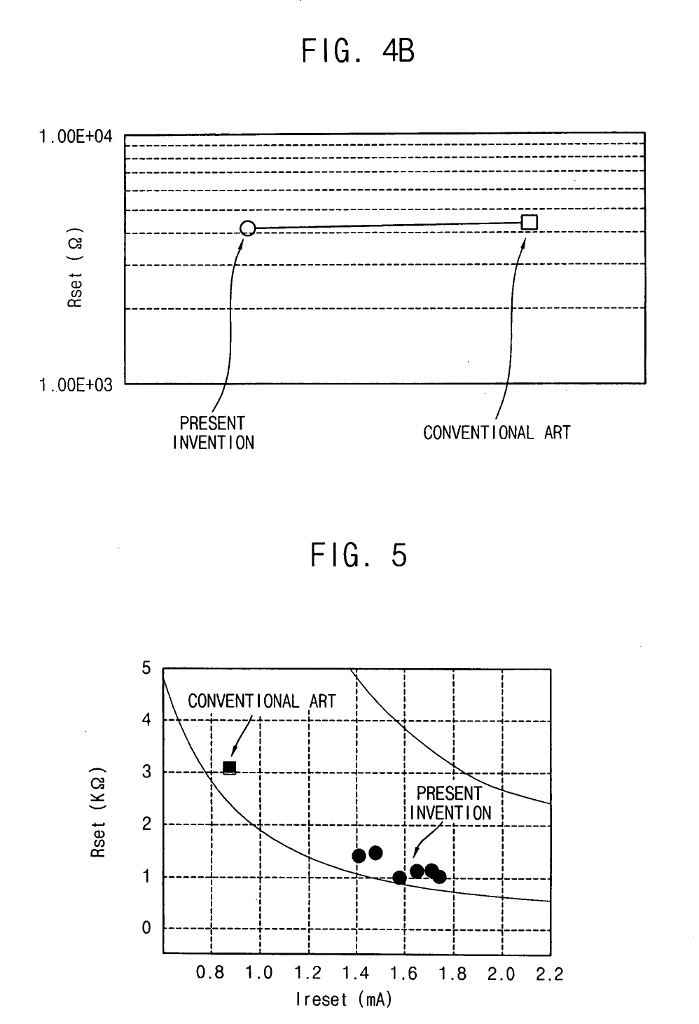

FIG. 5 is a graph illustrating electrical properties of a conventional phase-changeable memory device and a phase-changeable memory device of some embodiments of the present invention based on a difference in a refraction index of silicon oxynitride.

Referring to FIG. 5, a horizontal axis and a vertical axis represent a reset current (mA) and a set resistance (kΩ), respectively. “▪” represents the reset current and the set resistance of the conventional phase-changeable memory device including an insulating interlayer densified by an annealing process performed after the insulating interlayer is formed by depositing silicon oxynitride having a refraction index of about 2.1 at a low temperature of about 400° C. by a plasma-enhanced chemical vapor deposition (PECVD) process. “” represents the reset current and the set resistance of the phase-changeable memory device of some embodiments of the present invention including an insulating interlayer formed by depositing silicon oxynitride having a refraction index of about 2.1 at a high temperature of about 550° C. in a PECVD process.

Referring to FIG. 5, in the phase-changeable memory device of some embodiments of the present invention including the insulating interlayer having silicon oxynitride deposited at a high temperature of about 550° C., when the refraction index of silicon oxynitride is increased from about 1.8 to about 2.1 by varying a composition ratio of silicon oxynitride, the reset current increases compared with the reset current in the conventional phase-changeable memory device including the insulating interlayer having silicon oxynitride deposited at a low temperature of about 400° C., while the set resistance is substantially similar. The above effect shows that the phase-changeable transition efficiency decreases owing to a thermal conductivity difference based on the change of composition ratio of silicon oxynitride deposited at a high temperature of about 550° C. Accordingly, in some embodiments, the insulating layer including silicon oxynitride is formed to have a refraction index of about 1.7 to about 1.9. One possible reason as to why the above effect is generated is because a phase transition efficiency of a phase-changeable material layer is reduced by a difference in thermal conductivity due to a variation of the composition ratio of silicon oxynitride deposited at a relatively high temperature of about 550° C. Thus, the insulating interlayer including silicon oxynitride in some embodiments has a refraction index of about 1.7 to about 1.9 with a consideration of an electric characteristic of the phase-changeable memory device.

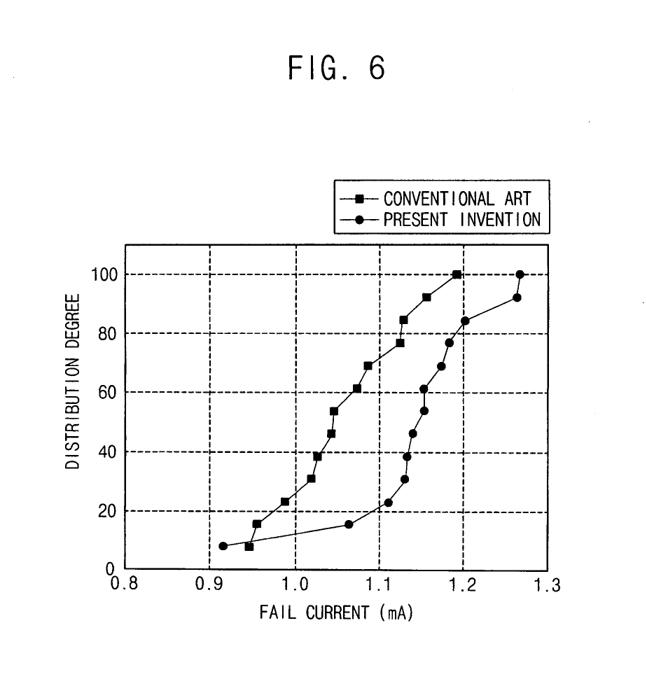

FIG. 6 is a graph for comparing insulation reliabilities of the insulating interlayers of a conventional phase-changeable memory device and a phase-changeable memory device of some embodiments of the present invention. More particularly, to selectively measure a reliability of the insulating interlayer, a region having defects is measured from a test pattern including an insulating interlayer on which a phase-changeable material layer is not formed using a sweeping voltage.

Referring to FIG. 6, a horizontal axis represents a fail current (mA). A vertical axis represents a distribution degree (%). “▪” represents the insulation reliability of the insulting interlayer formed by the conventional method in which silicon oxynitride having a refraction index of about 2.1 was deposited at a low temperature of about 400° C. by a plasma-enhanced chemical vapor deposition (PECVD) process. “” represents the insulation reliability of the insulating interlayer of some embodiments of the present invention formed by deposing silicon oxynitride having a refraction index of about 1.8 at a high temperature of about 550° C. in the PECVD process.

Referring to FIG. 6, the insulating interlayer of some embodiments of the present invention formed at a high temperature of about 550° C. may be relatively dense so that the insulating interlayer of the present invention has an insulation reliability superior to that of the conventional insulating interlayer that is formed at a low temperature of about 400° C. by PECVD process to have pores.

According to some embodiments of the present invention, silicon oxynitride is deposited at a relatively high temperature of about 450° C. to about 650° C. by a PECVD and/or a low pressure chemical vapor deposition (LPCVD) process so that an insulating interlayer located between a lower electrode and a phase-changeable material layer may be formed. A process for forming a contact connecting the lower electrode to the phase-changeable material layer may be then performed.

As described above, the insulating interlayer of some embodiments of the present invention is formed at a relatively high temperature of about 550° C. by a PECVD process so that the insulating interlayer may be denser than a conventional insulating interlayer that is formed at a relatively low temperature of about 400° C. to have pores. In addition, an insulation characteristic of the insulating interlayer of some embodiments of the present invention may be superior to that of the conventional insulating interlayer. Thus, a profile of a contact hole filled with the contact may not deteriorate when the process for forming the contact is performed even though an annealing process for densifying the insulating interlayer is not performed after the insulating interlayer is formed. For example, a sidewall of the contact hole may become bent. As a result, the profile of the contact hole filled with the contact connecting the lower electrode to the phase-changeable layer may be improved while maintaining an electrical property of a phase-changeable memory device including the insulating interlayer. In addition, processes for forming the phase-changeable memory device including the insulating interlayer may be simplified.

Some embodiments of the present invention provide a method of manufacturing a phase-changeable memory device, capable of improving a profile of a contact hole filled with a phase-changeable material layer connected to a lower electrode and realizing a simplification of processes.

In accordance with some embodiments of the present invention, there is provided a method of manufacturing a phase-changeable memory device. In the method, a lower electrode is formed on a substrate. Silicon oxynitride is deposited on the lower electrode at a temperature of about 450° C. to about 650° C. to form an insulating interlayer that is relatively dense on the lower electrode. The insulating interlayer is then partially etched to form a contact hole exposing the lower electrode. A phase-changeable material layer pattern filling up the contact hole is formed on the insulating interlayer such that the phase-changeable material layer pattern makes contact with the lower electrode. For example, the insulating interlayer may have a refraction index of about 1.7 to about 1.9. The insulating interlayer may be formed by a plasma-enhanced chemical vapor deposition process or a low pressure chemical vapor deposition process.

An etch stop layer may be further formed on the lower electrode before forming the insulating interlayer. The etch stop layer may be formed by depositing silicon nitride by a plasma-enhanced chemical vapor deposition process.

A hard mask may be further formed on the insulating interlayer before the contact hole is formed. The hard mask may be formed by depositing oxide by a plasma-enhanced chemical vapor deposition process.

A contact spacer may be further formed on sidewalls of the contact hole before forming the phase-changeable material layer pattern. The contact spacer may include silicon nitride deposited by a low chemical vapor deposition process.

A high resistance material layer may be further formed in the contact hole before forming the phase-changeable material layer pattern. The high resistance material layer may be formed using titanium aluminum nitride.

In accordance with some embodiments of the present invention, there is provided a method of manufacturing a phase-changeable memory device. In the method, an impurity region is formed at a substrate. An insulating layer is formed on the substrate. The insulating layer is partially etched to form a first contact hole exposing the impurity region. A lower electrode filling up the first contact hole is formed such that the lower electrode makes contact with the impurity region. Silicon oxynitride is deposited on the lower electrode at a temperature of about 450° C. to about 650° C. to form an insulating interlayer that is relatively dense. The insulating interlayer is partially etched to form a second contact hole exposing the lower electrode. A phase-changeable material layer pattern filling up the second contact hole is formed on the insulating interlayer such that the phase-changeable material layer pattern makes contact with the lower electrode.

According to some embodiments of the present invention, silicon oxynitride is deposited at a relatively high temperature of about 450° C. to about 650° C. by a plasma-enhanced chemical vapor deposition (PECVD) or a low pressure chemical vapor deposition (LPCVD) process to form an insulating interlayer between a lower electrode and a phase-changeable material layer pattern. A contact process is then performed to electrically connect the lower electrode to the phase-changeable material layer pattern.

The insulating interlayer of some embodiments of the present invention formed at a high temperature of about 550° C. has a dense layer property and an excellent insulation reliability compared with the a conventional insulating interlayer formed by a PECVD process at a low temperature of about 400° C. and having a porous layer property. Accordingly, without an additional annealing process for making the insulating interlayer dense after forming the insulating interlayer, the profile defect of the contact hole, such as bowing of the sidewalls of the contact hole formed on the lower electrode during a contact process, is not caused, to thereby simplify processes.

The insulating interlayer of some embodiments of the present invention is formed at a relatively high temperature of about 550° C. by a PECVD process so that the insulating interlayer of some embodiments of the present invention may be denser than a conventional insulating interlayer that is formed at a relatively low temperature of about 400° C. to have pores. In addition, an insulation characteristic of the insulating interlayer of some embodiments of the present invention may be superior to that of the conventional insulating interlayer. Thus, a profile of a contact hole filled with the contact may not be deteriorated when the process for forming the contact is performed even though an annealing process for densifying the insulating interlayer is not performed after the insulating interlayer is formed. For example, a sidewall of the contact hole may become bent. In addition, processes for forming the phase-changeable memory device including the insulating interlayer may be simplified.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a phase-changeable memory device, the method comprising:
forming a lower electrode on a substrate;
forming an insulating interlayer having a selected density on the lower electrode by depositing silicon oxynitride on the lower electrode at a temperature of about 450° C. to about 650° C.;
partially etching the insulating interlayer to form a contact hole exposing the lower electrode; and
forming a phase-changeable material layer pattern in the contact hole in the insulating interlayer that contacts the lower electrode.

2. The method of claim 1, wherein forming the insulating interlayer includes forming the insulating interlayer to have a refraction index of about 1.7 to about 1.9.

3. The method of claim 1, wherein forming the insulating interlayer includes forming the insulating interlayer using a plasma-enhanced chemical vapor deposition process and/or a low pressure chemical vapor deposition process.

4. The method of claim 1, wherein forming the insulating interlayer is preceded by forming an etch stop layer on the lower electrode.

5. The method of claim 4, wherein forming the etch stop layer includes depositing silicon nitride using a plasma-enhanced chemical vapor deposition process.

6. The method of claim 1, wherein partially etching the insulating interlayer is preceded by forming a hard mask on the insulating interlayer.

7. The method of claim 6, wherein forming the hard mask includes depositing oxide by a plasma-enhanced chemical vapor deposition process.

8. The method of claim 1, wherein forming the phase-changeable material layer pattern is preceded by forming a contact spacer on sidewalls of the contact hole.

9. The method of claim 8, wherein forming the contact spacer includes depositing silicon nitride using a low chemical vapor deposition process.

10. The method of claim 9, wherein forming the insulating interlayer includes depositing silicon oxynitride at a temperature of about 550° C. and wherein forming the contact spacer includes depositing a nitride at a temperature of about 650° C. to about 750° C.

11. The method of claim 1, wherein forming the phase-changeable material layer pattern is preceded by forming a high resistance material layer in the contact hole.

12. The method of claim 11, wherein forming the high resistance material layer includes forming the high resistance material layer using titanium aluminum nitride.

13. The method of claim 1, wherein the phase-changeable material layer fills the contact hole.

14. A method of manufacturing a phase-changeable memory device, the method comprising:
forming an impurity region in a substrate;
forming a first insulating layer on the substrate;
partially etching the first insulating layer to form a first contact hole exposing the impurity region;
forming a lower electrode filling the first contact hole that contacts the impurity region;
forming a second insulating layer having a selected density on the lower electrode by depositing silicon oxynitride on the lower electrode at a temperature of about 450° C. to about 650° C.;
partially etching the second insulating layer to form a second contact hole exposing the lower electrode; and
forming a phase-changeable material layer pattern filling the second contact hole that contacts the lower electrode.

15. The method of claim 14, wherein forming the second insulating layer includes forming the second insulating layer to have a refraction index of about 1.7 to about 1.9.

16. The method of claim 14, wherein forming the second insulating layer includes forming the second insulating layer using a plasma-enhanced chemical vapor deposition process and/or a low pressure chemical vapor deposition process.

17. The method of claim 14, wherein forming the second insulating layer is preceded by forming an etch stop layer including silicon nitride on the lower electrode and the first insulating layer using a plasma-enhanced chemical vapor deposition process.

18. The method of claim 14, wherein partially etching the second insulating layer is preceded by forming a hard mask including oxide on the second insulating layer using a plasma-enhanced chemical vapor deposition process.

19. The method of claim 14, wherein forming the phase-changeable material layer pattern is preceded by forming a contact spacer including silicon nitride on sidewalls of the second contact hole using a low-pressure chemical vapor process.

20. The method of claim 14, wherein forming the phase-changeable material layer pattern is preceded by forming a high resistance material layer including titanium aluminum nitride in the second contact hole.
